(19) United States
(12) Patent Application Publication
(10) Pub. No.: US 2025/0199089 A1
(43) Pub. Date: Jun. 19, 2025

(54) SERVERS, SYSTEMS, AND METHODS FOR DETERMINING DATA QUALITY ISSUES FOR TRANSFORMERS IN AN ELECTRICAL DISTRIBUTION NETWORK

(71) Applicant: PACIFIC GAS AND ELECTRIC COMPANY, Oakland, CA (US)

(72) Inventors: Devon Yates, Boulder, CO (US); Arvind Simhadri, Palo Alto, CA (US); Jacinto Chen, San Francisco, CA (US); Ryan Scarbrough, Plano, TX (US)

(21) Appl. No.: 18/982,995

(22) Filed: Dec. 16, 2024

Related U.S. Application Data
(60) Provisional application No. 63/610,167, filed on Dec. 14, 2023.

(51) Int. Cl. G01R 31/62; H02J 13/00

(52) U.S. Cl. CPC G01R 31/62; H02J 13/00002; H02J 13/00032; H02J 13/00001

(57) ABSTRACT

In some embodiments, the disclosure is directed to a system for estimating high-side voltage of transformers in an electrical distribution network. In some embodiments, the system executes program instructions that enable one or more computers to receive meter load and/or voltage data from smart meters. In some embodiments, the data is used in transformer load analysis to assume impedance values, determining low-side voltage, and estimating high-side voltage using the determined low-side voltage. In some embodiments, the system is configured to these estimations against known values to identify discrepancies, which are output via a graphical user interface. In some embodiments, the system is configured to determine expected percent impedance from historical data and/or estimate impedance characteristics. In some embodiments, the system is configured to execute clustering of voltage estimates to identify similar phases among neighboring transformers.

### CROSS-REFERENCE TO RELATED APPLICATION

This application claims the benefit of U.S. Provisional Patent Application No. 63/610,167, filed Dec. 14, 2023, which is incorporated by reference herein in its entirety.

### BACKGROUND

Record errors and energy diversion can overload transformers and may not be identified by existing methods of monitoring, which include monitoring the peak coincident meter load on the transformers. Additionally, existing methods may misdiagnose overloading when a different transformer than one of record is being used. Consequently, it is difficult to determine which transformers are overloaded due to data quality errors in transformer misassignments, incorrect asset information, and energy diversion.

Overloaded transformers are a fire and service quality risk because they can prematurely fail, resulting in ignitions or unplanned outages. The mechanism for transformer failure due to overloading is generally due to premature deterioration of the insulation in the transformer due to thermal aging. Short term overloading is allowable, but long-term overloading will result in aging of insulation with the aging being exponentially related to the heating of the transformer. Long term overloading does not directly result in catastrophic failure, but rather in the failure of the insulation either resulting in a windings failure or a fault.

Extreme overloading may cause potential ignition. A threshold of 200% of rated loading is a risk factor for these types of failures, and is associated with the generation of gas bubbles and related failures at an assumed temperature threshold. Additionally, because of the relationship of overload related failure to heat and loading, there is a reliability impact during heat waves when heat waves occur. There can be many simultaneous failures of transformers in a single area, leading to extended outages at times when energy is urgently needed.

Therefore, there is a need in the art for a system that can predict transformer failure and/or control equipment to prevent overload.

### SUMMARY

In some embodiments, the disclosure is directed to a system for estimating high-side voltage of transformers in an electrical distribution network. In some embodiments, the system includes one or more computers comprising one or more processors and one or more non-transitory computer readable media, the one or more non-transitory computer readable media comprising program instructions stored thereon that when executed cause the one or more computers to execute one or more steps of an algorithm. Some embodiments include a step to receive, by the one or more processors, meter load and voltage data from one or more smart meters coupled to one or more transformers. Some embodiments include a step to execute, by the one or more processors, an assumption for an impedance value for each of the one or more transformers. Some embodiments include a step to determine, by the one or more processors, low-side voltage of a transformer using the assumption. Some embodiments include a step to execute, by the one or more processors, an estimation of a high-side voltage of the transformer using the determined transformer low-side voltage. In some embodiments, the system is configured to compare the estimation against known high-side voltage estimates to identify one or more discrepancies. In some embodiments, the system is configured to output a graphical user interface with the one or more discrepancies.

In some embodiments, the one or more non-transitory computer readable media include further program instructions stored thereon configured to cause the one or more computers to optimize, by the one or more processors, impedance selection to minimize error between estimated and measured voltages. In some embodiments, the system is configured to execute clustering of voltage estimates to identify similar phases among neighboring transformers. In some embodiments, the system is configured to alert users through the graphical user interface when the estimated high-side voltage deviates beyond a predefined threshold from the known high-side voltage estimates.

In some embodiments, the one or more non-transitory computer readable media comprise further program instructions stored thereon that cause the one or more computers to determine, by the one or more processors, an expected percent impedance for the one or more transformers from historical and specification data. In some embodiments, the system is configured to estimate impedance characteristics based on smart meter voltage and/or load readings on a low-side of the one or more transformers. In some embodiments, the system is configured to generate reports of voltage estimations and/or detected transformer variances.

In some embodiments, the one non-transitory computer readable media comprise further program instructions stored thereon that cause the one or more computers to determine, by the one or more processors, a relationship between calculated voltage drop and expected impedance values for anomaly detection. In some embodiments, the system is configured to correct for discrepancies in transformer records by using neighbor transformer comparisons. In some embodiments, the system is configured to output corrected transformer parameters as an input into voltage drop calculations.

In some embodiments, the system is configured to refine the estimation of the high-side voltage using collected data. In some embodiments, the system is configured to adjust calculations based on clustering analysis of other transformers in similar network conditions. In some embodiments, the system is configured to leverage historical voltage drop data to optimize transformer voltage estimation models. In some embodiments, the system is configured to enable users to manually input one or more values for calculated impedances and voltage estimations.

In some embodiments, the non-transitory computer readable media comprise further program instructions stored thereon that cause the one or more computers to execute, by the one or more processors, near real-time voltage estimation updates during identified network loading changes. In some embodiments, the system is configured to employ a comparative analysis of neighboring transformer high-side estimates. In some embodiments, the system is configured to send a notification upon detecting repeated discrepancies. In some embodiments, the system is configured to enable a user to define a preconfigured risk level for the one or more transformers. In some embodiments, the system is configured to execute a threshold notification at the preconfigured risk level.

### DRAWING DESCRIPTION

FIG. 1 shows a non-limiting system architecture according to some embodiments.

FIG. 2 shows a simplified example of the measurements available on a single-phase transformer according to some embodiments.

FIG. 3 shows a summary of a system (TOAM) algorithm according to some embodiments.

FIG. 4 shows a non-limiting example table of assumptions according to some embodiments.

FIG. 5 illustrates a secondary simplified circuit with 4 equations and 5 unknowns according to some embodiments.

FIG. 6 illustrates Ohm's Law and Krchov's Current Law according to some embodiments.

FIG. 7 illustrates a high-side simplified circuit and ensemble slope equation according to some embodiments.

FIG. 8 illustrates a table of diagnostics outputs by the system according to some embodiments.

FIG. 9 shows a radial secondary assumption according to some embodiments.

FIG. 10 shows a branched secondary assumption according to some embodiments.

FIG. 11 shows connection type base on configuration according to some embodiments.

FIG. 12 shows an example of an issue found to have a service drop which was melting its insulator and causing an increase in the observed impedance at the smart meters in accordance with some embodiment.

FIGS. 13-15 show the results of the model according to some embodiments.

FIGS. 16-18 show the iterative process of convergence on actual values in accordance with some embodiment.

FIG. 19 illustrates a system generated alert where the reference slope deviates significantly from the observed slope in accordance with some embodiment.

FIGS. 21A and 21B illustrate various system generated reports according to some embodiments.

FIGS. 22A and 22B illustrate a system generated GUI according to some embodiments.

FIG. 23 shows a desktop review according to some embodiments.

FIG. 24 illustrates neighbor identification according to some embodiments.

FIG. 25 shows a system generated map according to some embodiments.

FIG. 26 shows a lean dashboard according to some embodiments.

FIG. 27 shows noise measurement according to some embodiments.

FIG. 28 illustrates a first example of observing situations where more clusters are identified than should exist according to some embodiments.

FIG. 29 shows that sometimes a cluster that categorized as noise will disrupt the impedance estimates of the other members in accordance with some embodiment.

FIG. 30 illustrates that sometimes phases will be characterized as noise even though they are apparently in the same phase in accordance with some embodiment.

FIG. 31 illustrates a computer system 110 enabling or comprising the systems and methods in accordance with some embodiments.

### DETAILED DESCRIPTION

The following non-limiting detailed description is directed to a system for identifying data quality errors relating to transformers according to some embodiments. In some embodiments, the system is configured to receive historical transformer data to evaluate whether a transformer is overloaded. In some embodiments, the system includes an Electric Distribution Transformer Loading Manager (EDTLM) platform, which may be a part of one or more modules of the computer framework described herein. In some embodiments, the EDTLM platform is configured to combine smart meter and billing data along with transformer configurations (e.g., ratings) to calculate coincident monthly peak and average loading on each transformer. In some embodiments, the EDTLM is configured to calculate the peak loading for one or more (e.g., all) transformers in the electrical distribution system. In some embodiments, the EDTLM includes a comprehensive database of (all) transformers within the distribution system, including their locations, types, and/or capacities, as non-limiting examples. In some embodiments, EDTLM inputs may include historical usage data, current loading conditions, weather data, voltage levels, and/or system configurations. In some embodiments, the EDTLM determines when a transformer is operating at or near its maximum capacity. In some embodiments, the EDTLM includes visualization tools to display the data, including maps and graphs, and generates reports, as further described herein. In some embodiments, the EDTLM is configured to generate maintenance alerts or notifications when a transformer approaches a critical load condition, which can help prevent failures and improve reliability.

In some embodiments, the EDTLM platform is configured to summarize the overloading of transformers where the configuration and metadata is accurate. The association of service points to transformers that are incorrect can result in inaccurate interval loading. In some situations, the transformer asset metadata is incorrect, and the capacity is inaccurate. In some embodiments, when these errors occur, the loading and overloading assessment calculations will result in false positives and false negatives. The false positives result in wasted resources, and false negatives result in hidden reliability and ignition risk.

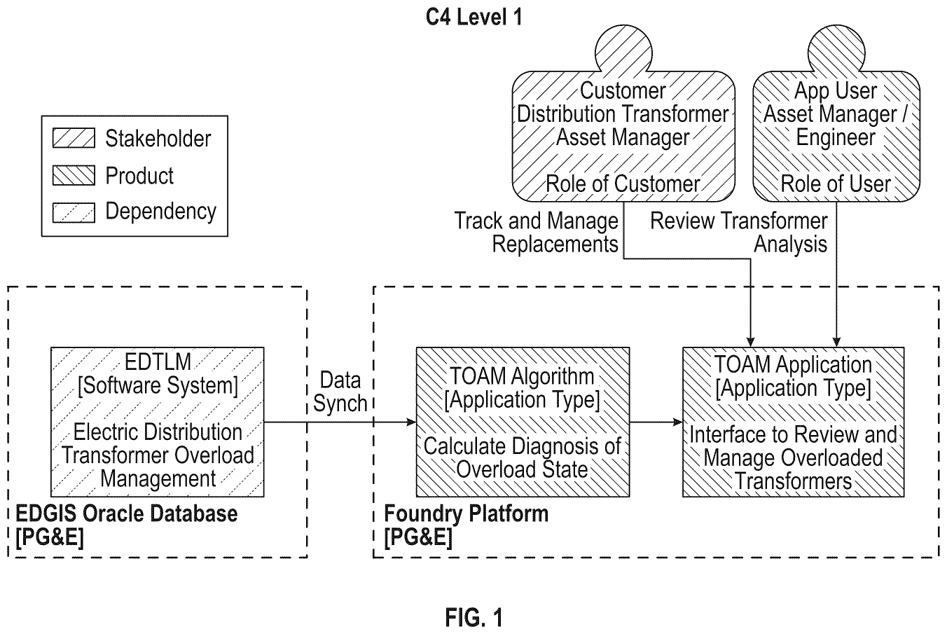

FIG. 1 shows a non-limiting system architecture according to some embodiments. In some embodiments, the system includes a Transfer Overload Accuracy Model (TOAM) platform. In some embodiments, the TOAM platform includes a TOAM algorithm, represented by the steps and functionality below, and a TOAM application which includes one or more program modules executed by the system.

In some embodiments, the TOAM platform is configured to receive data from the EDTLM platform for input into a model, which may include asset data and/or smart meter data, such as interval data. In some embodiments, the TOAM platform is configured to receive estimated impedances for all neighbor transformers from the perspective of each individual transformer. In some embodiments, the TOAM platform is configured to receive timeseries metadata associated with the service point phase level impedance estimates.

In some embodiments, the system is configured to identify transformers which are currently identified as overloaded by the EDTLM platform. In some embodiments, in addition to the overloading status of the transformers from EDTLM, the system is configured to provide a TOAM diagnosis, which includes an indication of whether the observed voltage behavior is consistent with the loading from smart meters and/or identify whether a transformer identified as overloaded in EDTLM is truly overloaded or is “suspicious.” In some embodiments, transformers which are not currently identified as overloaded in EDTLM but are behaving as if they are overloaded are identified by the system as suspicious.

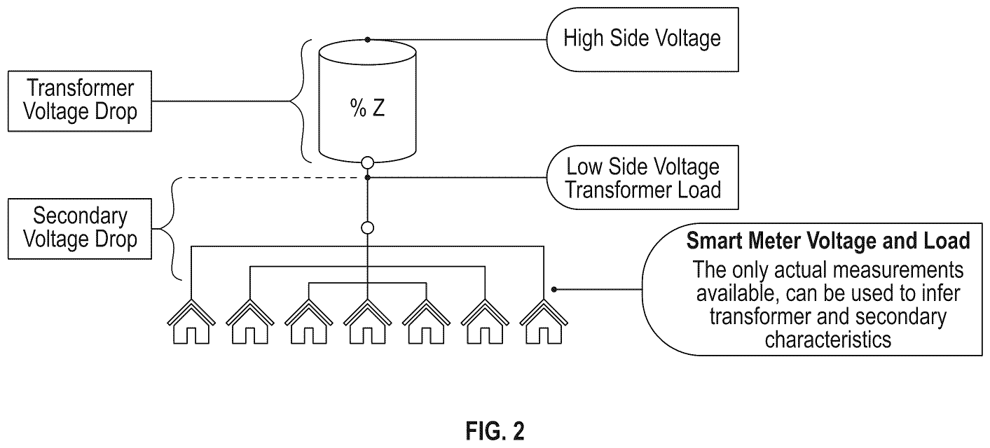

FIG. 2 shows a simplified example of the measurements available on a single-phase transformer according to some embodiments. Distribution transformers are the transformers which step voltage down from the medium voltage system to the low voltage system, to which customers' electrical panels are typically connected. In some embodiments, there are not voltage or load measurement on the distribution transformers, but there are load and voltage readings on the smart meters at the customer panels, and there are records which associate the smart meter to the transformer. In some embodiments, the transformers and smart meters can have different configurations, voltage levels, and may be single phase or multiphase. In some embodiments, the high-side voltage is connected to the medium level voltage from the primary conductors. In some embodiments, the low side voltage is the secondary level, and the smart meters are connected after a service drop.

In some embodiments, an impedance characteristic refers to the inherent electrical property of a transformer that quantifies its opposition to the flow of alternating current (AC). In some embodiments, this characteristic is expressed as a percentage, known as percent impedance (% Z), which is derived from the transformer's design specifications. In some embodiments, the system is configured to use the manufacturing specs of a transformer to determine the expected percent impedance, % Z, which represents the expected voltage drop expected at 100% of rated load. In some embodiments, if the high-side and low side voltages were able to be measured, it would be possible to measure voltage drop across the transformer and then estimate percent impedance as a function of the loading. Given a measured Z %, this could be compared to the expected value in the records, and where discrepancies are found this could indicate problems in the asset data or loading data according to some embodiments.

Currently, only smart meter voltages on the low side are known; however, the voltage at either side of the transformer is needed to calculate actual impedance. If the secondary network characteristics and transformer impedance characteristics were exactly known, then Ohm's and Kirchov's Laws could be used to sum up the loads, apply the losses, and exactly calculate the voltages on the high and low side of the transformer. In some embodiments, if actual impedance is known, the actual impedance is compared to expected impedance by the system to identify discrepancies (e.g., maintenance or diversion). In some embodiments, when the high and low side voltages are not available, they must first be estimated by the system. The details of a novel way to determine actual voltage is described below.

In some embodiments, estimated characteristics of the secondary are used to estimate low side voltages of the transformer for given smart meter voltage and load. The term secondary, in some embodiments, refers to the secondary winding or secondary side of a transformer. The secondary is the output side of the transformer that delivers power to the connected load, in contrast to the primary, which is the input side connected to the power source. In some embodiments, the system is configured to look at one or more transformers in a neighborhood of transformers and select similarly configured transformers to calculate an estimate of the high-side voltage. In some embodiments, the system is configured to determine a transformer voltage drop. In some embodiments, the system is configured to extract a percent impedance (% Z). In some embodiments, the system is configured to compare percent impedance to what is known about transformer impedance. In some embodiments, the system is configured to identify discrepancies between how the voltage drop on the transformer is behaving as compared to how the transformer voltage should be behaving.

Some embodiments include a step to estimate characteristics of the secondary in order to estimate low side voltages of the transformer for given smart meter voltage and load. Some embodiments include a step to look at the neighborhood of transformers and select similarly configured transformers to get an estimate of the high-side voltage. Some embodiments include a step to determine the transformer voltage drop. Some embodiments include a step to extract the percent impedance. Some embodiments include generating a report which includes the percent impedance and/or one or more identified overloaded components, which may be displayed on a GUI and/or output as a notification (e.g., email, text, work order, etc.).

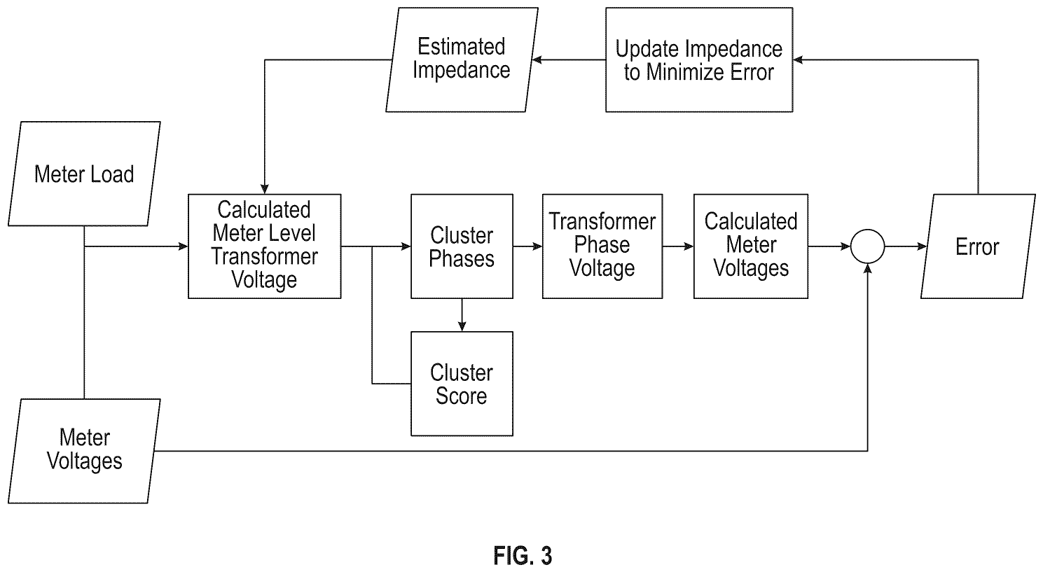

FIG. 3 shows system executed algorithm steps of the TOAM algorithm according to some embodiments. In some embodiments, the TOAM algorithm is configured to create a sufficiently accurate estimate of the high and low side transformer voltage to determine if the voltage drop across a transformer matches expected drop according to calculations based on expected impedance. In some embodiments, the TOAM algorithm is configured to receive meter load and voltage. In some embodiments, the TOAM algorithm is configured to assume an impedance value for a transformer. In some embodiments, the TOAM algorithm is configured to calculate transformer low side voltage using assumed impedance. In some embodiments, the TOAM algorithm is configured to calculate meter voltages based on assumed impedance.

In some embodiments, the TOAM algorithm is configured to iterate assumed impedance until the assumed transformer low side voltage yields the same value as the actual meter voltage. In some embodiments, the TOAM algorithm is configured to estimate high-side transformer voltage by using calculated impedance from the low side calculation. In some embodiments, the TOAM algorithm is configured to estimate high-side transformer voltage using a similar iteration as used in the transformer low side voltage calculation, but instead of meter voltage, the algorithm uses the transformer voltage previously calculated as the low side estimate.

Some embodiments include a step to take meter load and voltage. Some embodiments include a step to assume an impedance value for a transformer. Some embodiments include a step to calculate transformer low side voltage using assumed impedance. Some embodiments include a step to calculate meter voltages based on assumed impedance, which should provide the same answer as the actual meter voltage. Some embodiments include a step to iterate assumed impedance until error is minimized where transformer low side voltage yields the same as actual meter voltage. Some embodiments include a step to estimate high-side transformer voltage by using calculated impedance from low side calculation. Some embodiments include a step to use the low side estimate of transformer voltage previously calculated to execute the transformer high-side voltage calculation.

In some embodiments, the algorithm is executed continuously and/or periodically (e.g., weekly) to incorporate new EDTLM data and to generate time series of the resulting primary and secondary estimates. In some embodiments, the algorithm is (only) updated when the previous results of the analysis are showing poor performance and/or if the configuration of the transformer has changed. In some embodiments, this method can be used to identify mislabeled transformers and energy diversion. In some embodiments, if a transformer is showing impedance twice as much as expected, then it has characteristics of a transformer half its expected size, and may therefore be mislabeled, which the system is configured to identify.

In some embodiments, a list of in-service transformers is identified by the system, and enrichments are added to support user interface UI needs and other analysis needs. In some embodiments, the configuration of the transformer and the number of expected units obtained by the system is displayed on a graphical user interface. In some embodiments, transformer “units” may refer to complete transformer systems, such as a three-phase transformer provided as a single packaged product with one serial number. These units may be treated as single items for inventory or storage purposes. However, such transformer systems often include multiple components or “sub-units,” such as the individual windings or cores corresponding to each phase in a three-phase configuration. In some embodiments, the system is configured to generate separate records for each individual sub-unit to represent the true functional components of the transformer system. Additionally, in some embodiments, the system may parse label information provided on the transformer to extract key specifications, such as expected voltage levels, phase configuration, and the number of units or sub-units.

In some embodiments, for each transformer, the configuration is put into groups by the system as to whether the transformer is line-to-line or line-to-neutral on the high and low side, which supports calculation of the neighborhood groups. In transformer systems, the terms line-to-line and line-to-neutral describe the configuration of the transformer windings and their connection to the electrical system. A line-to-line configuration refers to a setup where the transformer winding is connected directly between two phase wires, commonly seen in a delta (Δ) connection. In such cases, no neutral wire is involved, and the voltage between the two phases (line-to-line voltage) is higher than the line-to-neutral voltage by a factor of √3 in a balanced three-phase system. This configuration is typically used in industrial applications requiring higher voltage without a neutral, such as powering motors or heavy machinery. Conversely, a line-to-neutral configuration describes a setup where the transformer winding is connected between a single-phase wire and a neutral wire, which is characteristic of a wye (Y) connection. This arrangement provides a lower line-to-neutral voltage, making it suitable for applications requiring a neutral wire, such as residential or light commercial installations. The high side of a transformer, which connects to the power source, is often configured for higher voltage, while the low side, which delivers power to the load, is typically designed for lower voltage. For example, a transformer with a high side configured in a line-to-line arrangement may receive 480V in a delta connection, whereas the low side may deliver 120V in a line-to-neutral wye configuration with a neutral available.

In some embodiments, unit information is compiled by the system for each transformer. In some embodiments, a record is created for each true unit in the transformer using the expected unit levels. In some embodiments, the system is configured to make a copy of the “unit” record and/or add a “bank ID” (bank identification) to enable distinction between units. In some embodiments, a bank ID refers to an identifier that distinguishes between different banks of transformers or transformer sub-units within a system. In some embodiments, a bank represents a group of transformers or transformer components that operate together as a functional unit, such as a three-phase transformer bank consisting of three single-phase transformers.

The inclusion of a bank ID in the record allows the system to track and manage individual units or sub-units while still associating them with their respective bank. For example, in a three-phase transformer system, each phase may have its own unit record, but all three records could share the same bank ID to indicate that they belong to the same transformer bank. By assigning a bank ID, in some embodiments, the system ensures clear organization and prevents confusion between units that may otherwise appear identical but belong to different functional groups.

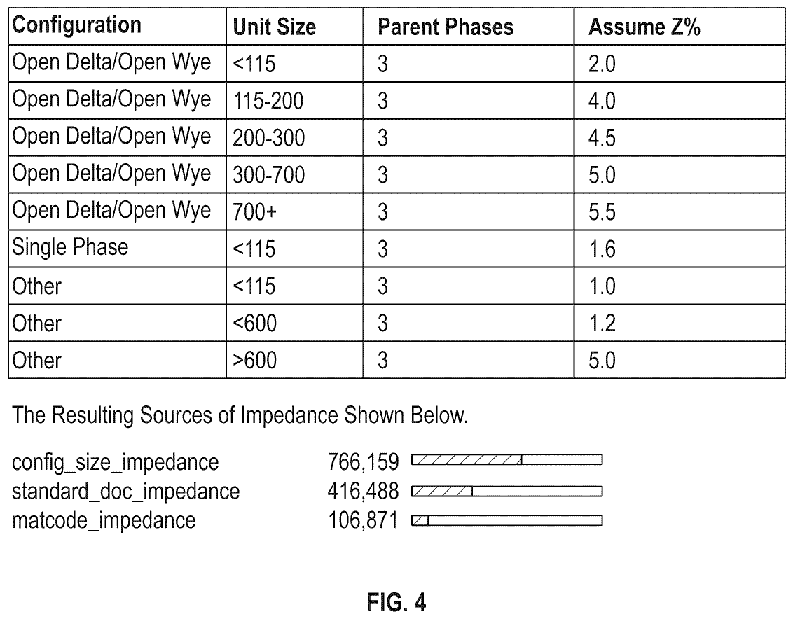

In some embodiments, to evaluate the expected slope of the transformer impedance, the rated capacity must be known, and the nameplate (labeled) Z % must be known. In some embodiments, this data is not recorded in asset data accessible by the system. In some embodiments, the system is configured to determine if the material code (matcode) of the unit is known, and/or if the Z % associated with that material code is known; if so, then that value is used by the system. In some embodiments, a material code is only available for a portion of the transformers. In some embodiments, when the material code is not available for the transformer, the system is configured to use a standards document, where the year, kVA, and/or operating voltage of the transformer are used to match to a record. In some embodiments, the system may determine the transformer's configuration and rated kVA, executing lookup table assumptions to derive the necessary data. FIG. 4 shows a non-limiting example table of assumptions according to some embodiments.

In some embodiments, a data set of service point phase information is generated by the system. In some embodiments, this dataset includes information such as the nominal voltage of the phase, and the expected configuration of the phase, e.g., split phase, line-to-line, stinger leg, etc. In some embodiments, flags are added by the system if the voltages or phasing are incompatible with the transformer. In some embodiments, an expected load distribution on the phases of the service point is calculated by the system.

In some embodiments, the nearby transformers are identified by the system. In some embodiments, this is accomplished by creating a network model (graph) of the circuit and running a nearest neighbor ranking on the conductor distance. In some embodiments, to identify the comparable neighbors, transformers which have comparable high and low side configurations are grouped by configuration style by the system. As a non-limiting example, transformers that are high-side line-to-line and low-side line-to-line would be in one group. In some embodiments, a plurality of transformers (e.g., 12) are selected by the system for the neighborhood.

In some embodiments, to prepare voltage data, the voltage data is normalized on a per unit basis by the system. In some embodiments, flags are applied by the system to the data to identify quality issues such as outliers, configuration conflicts, and/or large changes in loading relative to historical and/or expected loading.

In some embodiments, to prepare interval load data, the interval load is converted to kW at a predetermined interval (e.g., the top of the hour). In some embodiments, the interval is hourly; in some embodiments, the interval is 15 minutes. In some embodiments, no correction is made to align the averaging period, as it is assumed that the 15 minutes that are closer to the voltage reading are better for these purposes. In some embodiments, a conversion to kVA is made by the system using the power factor assumptions of the customer where measured values are not available.

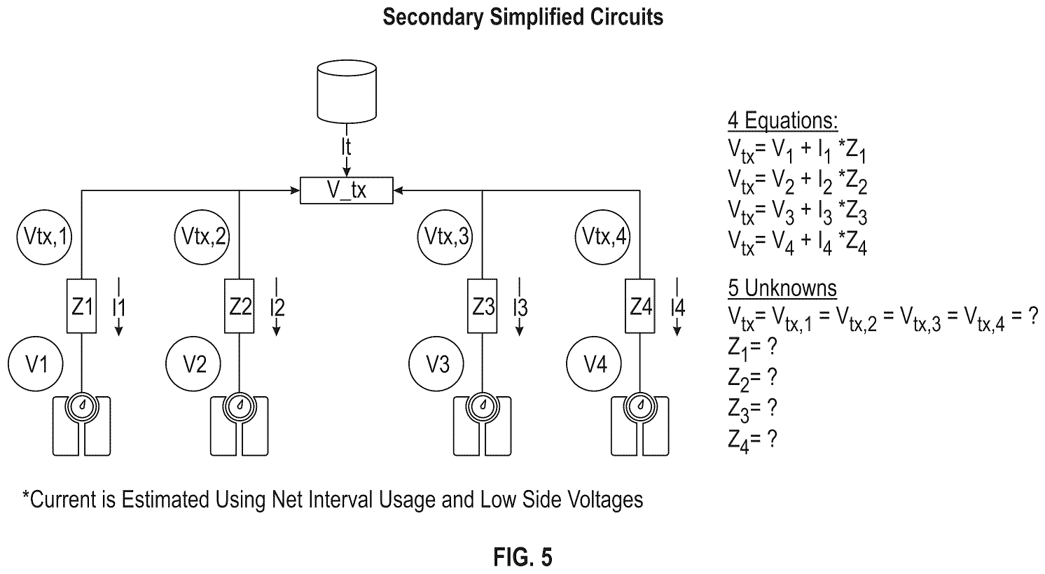

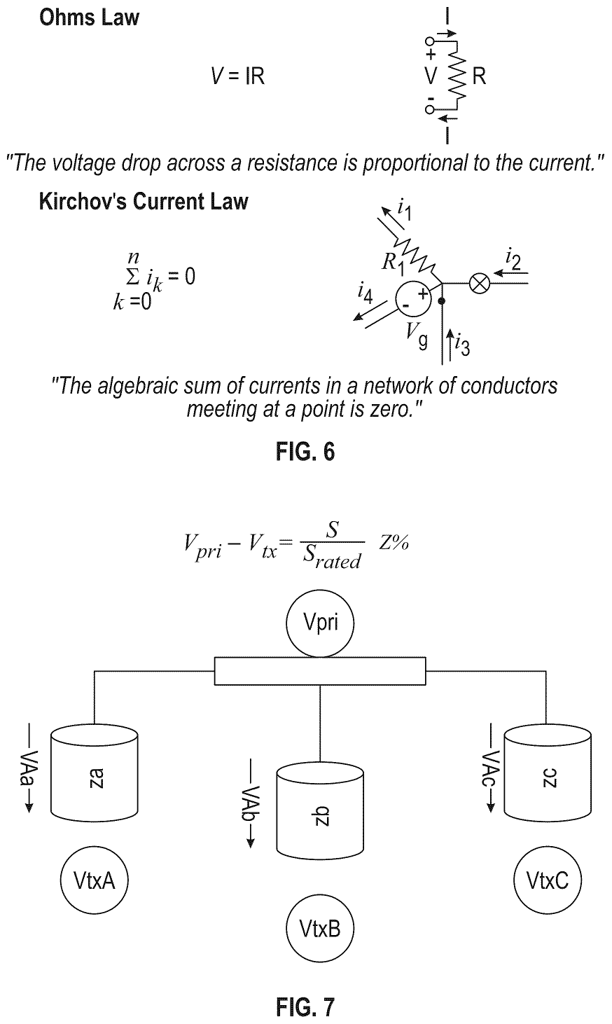

In some embodiments, to create the physics model executed by the system, a low-side model and a high-side model are included. In some embodiments, on the low-side of the transformer, the transformer voltage (V_tx) could in theory be estimated if the impedance Z, and current, I, were known. In some embodiments, to estimate the low-side transformer voltage, there are 4 equations, but there are 5 unknowns. FIG. 5 illustrates a secondary simplified circuit with 4 equations and 5 unknowns according to some embodiments. FIG. 6 illustrates Ohm's Law and Kirchhoff's Current Law.

In some embodiments, the voltage calculated from each member (each individual component or entity within the set of equations or circuit elements contributing to the calculation) should get the same result. In some embodiments, the system is configured to use the values varying over time with load to generate an optimization to identify the impedances needed to meet a constraint. In some embodiments, when there are not enough meters on the low-side relative to the number of phases, the low-side cannot be estimated, and all losses will manifest in the high-side analysis. However, because in most cases the low-side losses are very low, in some embodiments, this is not problematic.

As the smart meter load and voltage change, the transformer side voltage calculations should be equal. In some embodiments, the system is configured to estimate the transformer voltage and then back calculate the meter voltages, which should result the same answer for a normal transformer. This reverse computation checks whether the forward estimation of transformer voltage aligns with the meter voltages in a consistent way. If the transformer and meter voltages match under normal operating conditions, the backward calculation validates the accuracy of the model and the assumptions used in the estimation process. In some embodiments, the system is configured to optimize the selection of the impedance to minimize the error of the estimated voltages against the measured voltages.

In some embodiments, for the voltage on the high-side of the transformer, a similar approach to estimating the high-side voltage is used, but using the low-side voltage from the low side analysis as the starting point and using the neighboring transformers on the same phase as the members of the optimization and the primary voltage as the target. In some embodiments, the equation for the voltage drop is:

$${V}_{pri} = {V}_{tx} + \frac{S}{{S}_{rated}} * Z \%$$

where, S is the apparent power on the transformer, S_{rated} is the rated capacity of the transformer, and Z % is the percent voltage impedance from the nameplate.

In some embodiments, as a result of the high-side optimization, an estimate of the transformer Z % is made. However, in some embodiments this estimate can be sensitive to noise, misassignments and outliers. Therefore, in some embodiments, an “ensemble slope” is estimated, which is the slope of the line calculated, where Z % is best fit of the voltage drop of the transformer compared to average of the high-side voltage estimates of the neighboring transformers. FIG. 7 illustrates a high-side simplified circuit and ensemble slope equation according to some embodiments.

Referring back to FIG. 3, using the physics assumptions above, an optimization model is executed by the system to minimize the error in the estimate of the primary and/or secondary side parent transformer voltages in accordance with some embodiments. In some embodiments, for situations where a transformer is multi-unit, and/or the neighborhood is multiphase, as non-limiting examples, a clustering stage is introduced after the initial member level estimates of the parent voltages. In some embodiments, the clustering phase is configured to identify the separate phases at the parent level. In some embodiments, when the final parent phase voltage and load is calculated it is done within that grouping.

In some embodiments, optimization methods include optimization routines for solving both constrained and unconstrained optimization problems. In some embodiments, these routines are configured to find the minimum or maximum of a function by changing the parameters within specified constraints. In some embodiments, the system is configured to compute definite integrals, solve ordinary differential equations, and perform other integration tasks. In some embodiments, the system is configured to implement interpolation functions to estimate data points between existing data, which is useful for generating the curve fitting displays described herein. In some embodiments, the system is configured to execute linear algebra operations, including matrix factorization, solving linear systems of equations, and/or eigenvalue/eigenvector computations. In some embodiments, the system includes tools for filtering, convolution, Fourier transforms, and/or statistical functions and distributions. In some embodiments, the system is configured to solve nonlinear, constrained optimization problems.

In some embodiments, the system optimizes the problem by iteratively refining an approximation of the solution. In some embodiments, the system is configured to minimize the sum of squares of the cost function and constraint violations. In some embodiments, the system is configured to formulate the problem as a quadratic program. As a non-limiting example, the cost function can be implemented using the SciPy optimize minimize module, using the SLSQP (Sequential Least Squares Quadratic Programming) method from the SciPy library, as a non-limiting example of a suitable program. This method is used, in some embodiments, because the method enables the application of constraints, so that the solution space can be bounded to be positive and have an upper limit.

In some embodiments, clustering is implemented by using a Hierarchical Density-Based Spatial Clustering of Applications with Noise (HDBSCAN) algorithm. In some embodiments, HDBSCAN algorithm creates a hierarchical representation of clusters in the data, which is often visualized as a tree-like structure called a dendrogram. In some embodiments, this hierarchical approach provides a more comprehensive view of the data's clustering structure, allowing for the detection of clusters at different scales. Unlike some clustering algorithms that assume clusters have uniform density, in some embodiments, the HDBSCAN algorithm is configured to identify clusters with varying densities, which means the algorithm can find clusters of different shapes and sizes, adapting to the inherent density differences in the data. In some embodiments, the HDBSCAN algorithm does not require the user to specify the number of clusters in advance, making it useful in scenarios where the number of clusters is unknown or where clusters have complex shapes and sizes. In some embodiments, the HDBSCAN algorithm is more stable and less sensitive to the choice of parameters compared to some other clustering algorithms, and is computationally efficient, making it suitable for handling large datasets.

In some embodiments, this algorithm is used because as a density-based algorithm, it enables a variable number of clusters, and can classify records as noise. In some embodiments, selecting the correct parameters for the clustering process can be difficult, therefore the system is configured to execute a parameter search to tune the parameters to optimize against certain goals, including one or more of minimizing a difference between the number of clusters and the number of expected clusters; minimizing the items classified as noise; and maximizing the silhouette score of the clusters.

In some embodiments, certain phases should not be in the same cluster (e.g., phases on a multiphase meter or transformer). In some embodiments, this is implemented by applying a weighting to the distance matrix in the form of a constraint matrix. In some embodiments, for member pairs which should be in different clusters, the distance has a weighting factor that increases the distance between the pairs.

In some embodiments, the voltage of the parent is assumed to be the mean of all voltages in a phase cluster. In some embodiments, the max is considered, but is sensitive to misassignments and outliers. In some embodiments, the cost function is the root mean square error (RMSE) of the original voltage to the voltage calculated using the estimated parent voltage, impedance, and load.

In some embodiments, the system is configured to execute an overload assessment. In some embodiments, once the impedance is estimated, it can be compared to the assumed impedance. In some embodiments, if the two values do not match, the system is configured to generate potential causes for the errors. In some embodiments, if the estimated impedance is higher than the assumed impedance, this can be due to several causes:

In some embodiments, higher load on the transformer than records indicate one or more of:
i. Energy Diversion
ii. Customer Misassignment
iii. Non-Smart-meter Load
iv. Failing transformer, overloaded secondary or other peripheral equipment failure.

In some embodiments, smaller transformer installed than records indicate:
v. Transformer Record errors

In some embodiments, the system is configured to analyze algorithm failures. In some embodiments, if the estimated impedance is lower than the assumed impedance, then this can be due to several causes.

In some embodiments, lower load on the transformer than records indicate:
vi. Customer Misassignment

In some embodiments, larger transformer installed than records indicate one or more of:
vii. Transformer record errors
viii. Delay in as-built records

In some embodiments, there are several values that are calculated by the system using the adjusted impedance, which are used to support diagnosis of the overload state by the system.

In some embodiments, the EDTLM overload status and rate are calculated by taking the monthly coincident peak loading over the seasonal capability, to get the overload percent on a per unit basis. In some embodiments, a transformer is designated as overloaded if any unit has an overload percent greater than 100% in the past 12 months. In some embodiments, when a transformer is replaced, a reference overload is used, which only leverages the data from the months after the replacement for the purpose of scaling the adjusted overload.

In some embodiments, the system is configured to execute an adjusted capacity. In some embodiments, the capacity adjustment is a basic estimate of the size of transformer that may be installed at the location given the behavior of the transformer. In some embodiments, this adjustment includes two sources of information. In some embodiments, the first is a noise adjustment, where load that is classified as noise is assumed to reduce the overloading by ratio of that load to the total load for the week analyzed:

$$Noise Adjustment = 1 - Load classified as noise / Total Load$$

In some embodiments, the second is the ratio of the assumed impedance to the estimated impedance is use for an impedance adjustment:

Impedance adjustment=Estimated Impedance/Assumed Impedance

In some embodiments, a value called the adjusted capacity is then calculated, where:

Adjusted Capacity=Reference Seasonal Capacity*Impedance Adjustment

In some embodiments, the adjusted capacity cannot always be taken literally, in particular when there is energy diversion. However, the adjusted capacity provides a useful mechanism for the system to categorize whether the transformer is behaving as if it is overloaded or not according to some embodiments.

In some embodiments, the noise adjustment is scaled by the system using a portion of noise load at the time of the coincident peak loading. In some embodiments, the impedance adjustment may not be linear, as the loss rates for different transformer sizes are not linear to capacity.

In some embodiments, the system is configured to execute an overload rate adjustment. In some embodiments, the analysis is performed over a pre-determined time period (e.g., a week) and the overloading is monitored over the course of one or more years. In some embodiments, when calculating the overload diagnosis, the EDTLM result is used, and is adjusted to leverage the information from the analysis:

Adjusted Overload Rate=Peak Unit Load*Noise Adjustment/Adjusted capacity.

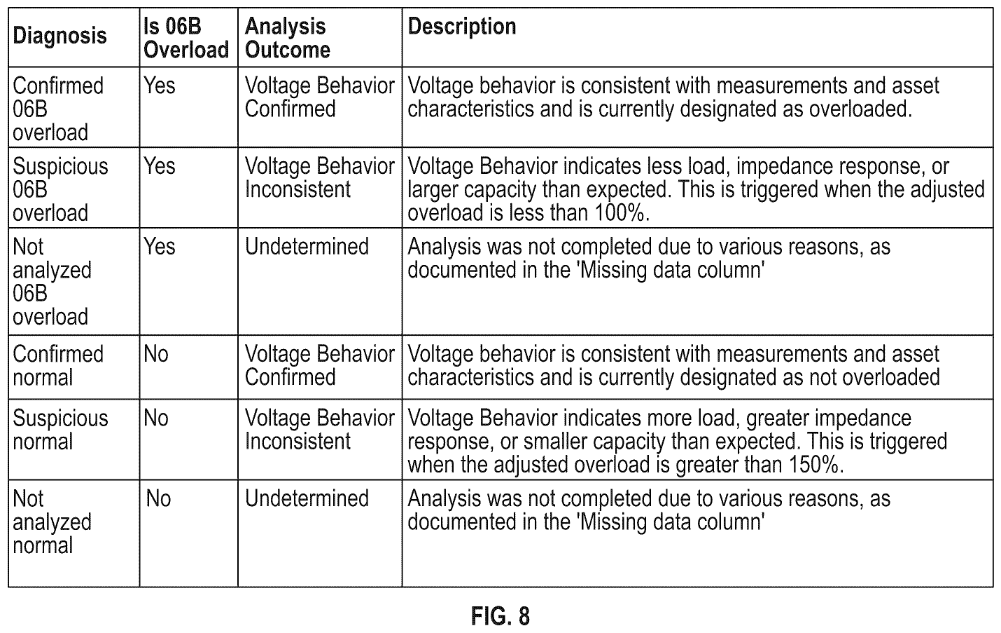

In some embodiments, the system is configured to execute a diagnosis function. In some embodiments, the diagnosis starts with the overloading status from EDTLM. In some embodiments, the status is either overloaded or normal, with a threshold of 100% of seasonal capability. FIG. 8 illustrates a table of diagnostics outputs by the system according to some embodiments.

In some embodiments, the analysis can fail for several reasons, some non-limiting examples are as follows: In some embodiments, if no customers are on the transformer, it cannot be analyzed. In some embodiments, if the load is too low, the variation of the voltage is too minimal to optimize around, therefore the analysis will return a not analyzed result when load is less than a threshold value. Over time, for most transformers, this should come down as higher loads are observed according to some embodiments. In some embodiments, if there are insufficient neighbors of the same configuration nearby, then the analysis will fail.

In some embodiments, if smart meters are present, and the transformer is behaving more overloaded than records indicate, the diagnosis will be not analyzed, because there may be unaccounted for load(s) confusing the algorithm.

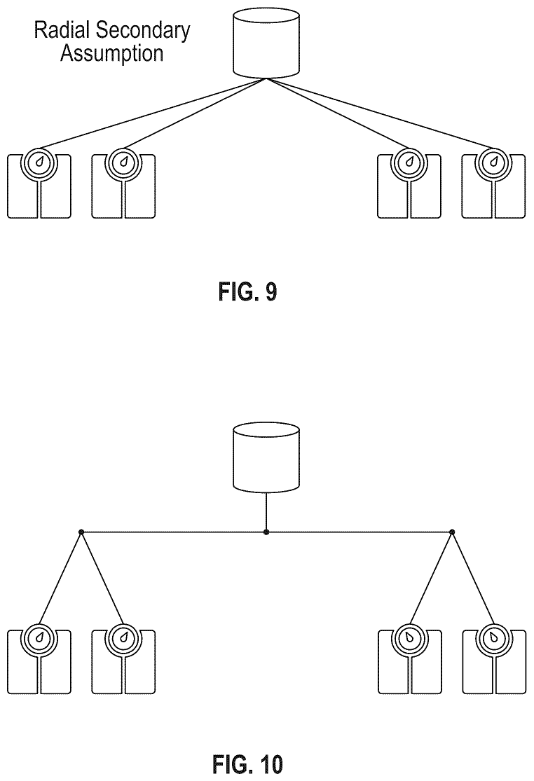

In some embodiments, there are several assumptions implemented by the system. In some embodiments, the TOAM algorithm is configured assumed that all service points on a transformer are connected radially to the low-side of the transformer. FIG. 9 shows a radial secondary assumption according to some embodiments.

This is not the case in reality, rather the transformer connects to a secondary, and the service points are connected by service drops to the secondary, according to some embodiments. In some embodiments, this branched configuration can result in overlapping load, which can make voltage drops from combined loads appear at the smart meter. In some embodiments, the system is configured to use a more detailed model of the secondary, which assumes a branched model of the secondary. In some embodiments, the system is configured to use a geospatial location of the service points to create an estimate of the secondary connection points. In some embodiments, the system is configured to treat the nodes as intermediate aggregation point in the voltage estimate process. FIG. 10 shows a branched secondary assumption according to some embodiments.

In some embodiments, the system is configured to execute smart meter interval data assumptions. In some embodiments, the smart meter voltages use substantially instantaneous reads, and the interval load is measured as energy, and is therefore a time averaged value of either 15 minute or hourly reads, for example. In some embodiments, because the smart meter fleet is predominantly hourly, only the hourly reads are used for the algorithm in this non-limiting example; however, any period would suffice. In some embodiments, the smart meter data is recorded in volts, and is converted into normalized per unit voltage by the system dividing by the assumed nominal voltage. In some embodiments, the nominal level of the voltage is not provided in records, and must be inferred from the observed voltage level and the meter form.

In some embodiments, the system is configured to execute transformer configuration assumptions. In some embodiments, transformer configuration assumptions include voltage level logic. In some embodiments, when a transformer has split phase service, where a 240 voltage level is split into two 120 phase services, for example, these voltage readings are added together by the system to get back to the 240 reading for analysis. In some embodiments, the enables comparison of the voltage readings to the neighborhood.

In some embodiments, transformer configuration assumptions include open delta configuration assumptions. In some embodiments, in an open delta transformer configuration analysis, there was a 208 voltage on the polyphase smart meters associated with the transformer. This voltage level is ambiguous when attempting to compare it to other voltage levels in the neighborhood, therefore, in some embodiments, the system is configured to exclude ambiguous data from the algorithm. However, in some embodiments, the system is configured to enable a user to keep it in. In some embodiments, this leg is included in the optimization but may cause problems when matching to normal phases.

In some embodiments, transformer configuration assumptions include phase assumptions. In some embodiments, the phasing on the low side is determined from the phase designation of the transformer. In some embodiments, it is 3 phase if the designation is ABC, and otherwise 1 phase. In some embodiments, the phasing on the high-side is determined by the maximum conductor phase designation of the upstream conductors of the members of the neighborhood.

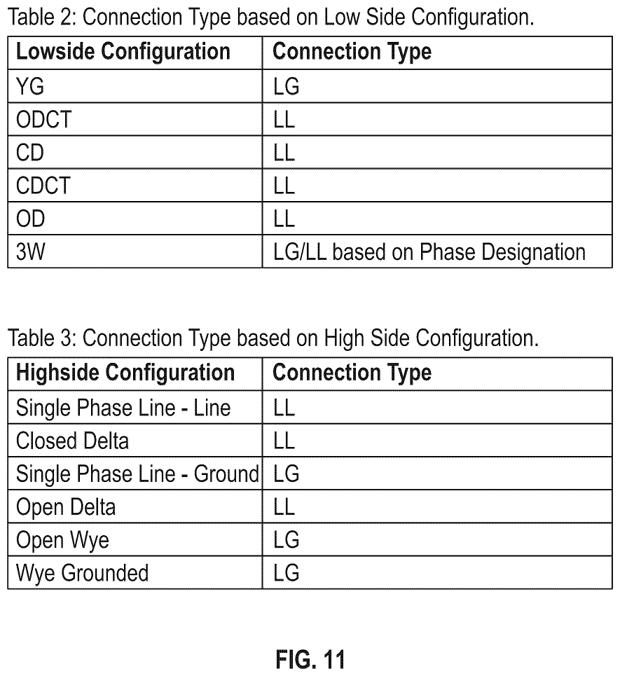

In some embodiments, transformer configuration assumptions include connection types. In some embodiments, when identifying neighborhoods, the system assumes that neighbors that can be compared will have the same configuration style, for example, a line-to-line connection on the high-side and a line-to-line connection on the low side. In some embodiments, where a transformer is line to neutral in a predominantly line-to-line neighborhood, this will cause the analysis to fail, because there are no comparable neighbors. FIG. 11 shows connection type base on configuration according to some embodiments.

In some embodiments, extensive validation was performed by looking at individual results using the user interface. In some embodiments, the system is configured to enable transformers that are flagged by the system to be investigated by looking at google street view, inspection records, notifications, misassignment flags, and/or EDTLM history, as non-limiting examples. In some embodiments, several situations were found where the rating of the transformer was visible in street view or inspection images and was different than the current asset records. In some embodiments, this was simply due to delays in records being ingested into the systems, but in other instances, the system identified data transcription errors, or missing records of replacements.

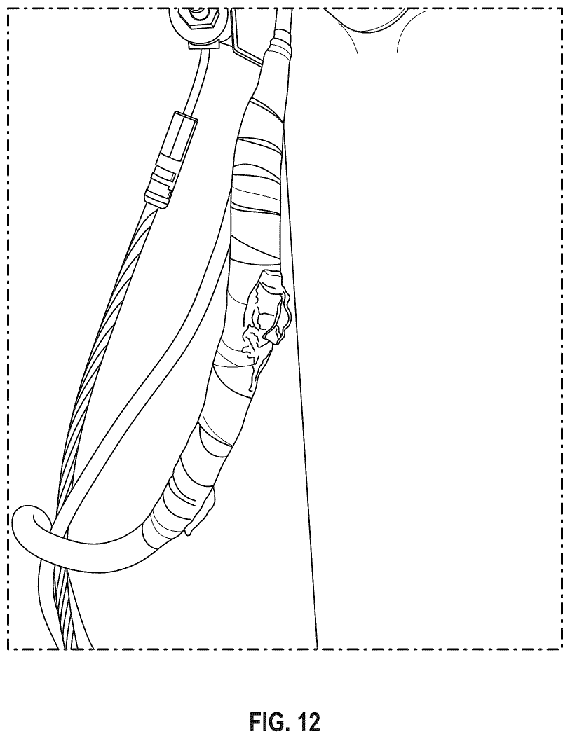

In some embodiments, field validation using a troubleman visit or installation of a remote voltage monitor (RVM) were used to validate overloads and underloads. In some embodiments, several energy diversion incidents were identified where customers were bypassing meters. FIG. 12 shows an example of an issue found to have a service drop which was melting its insulator and causing an increase in the observed impedance at the smart meters according to some embodiments.

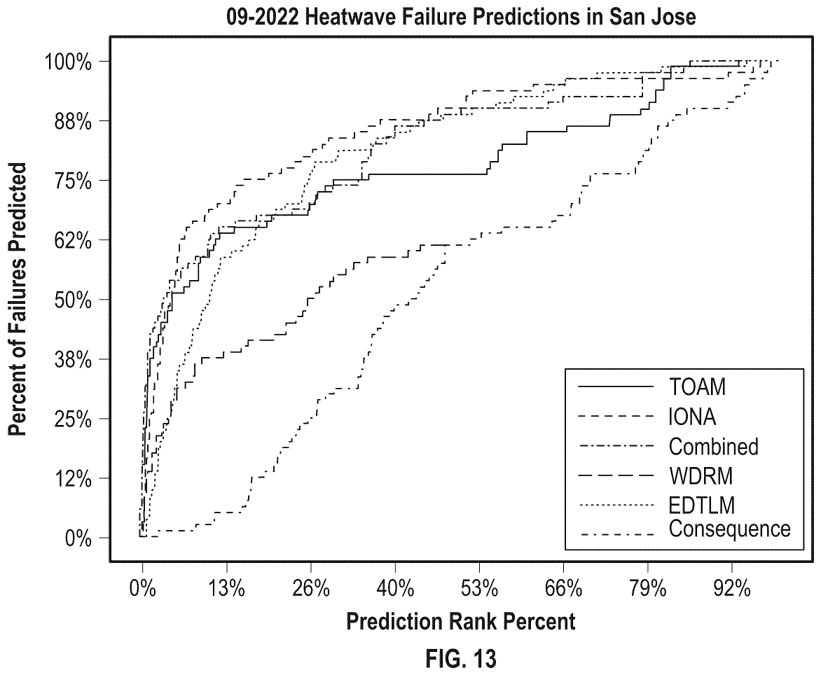

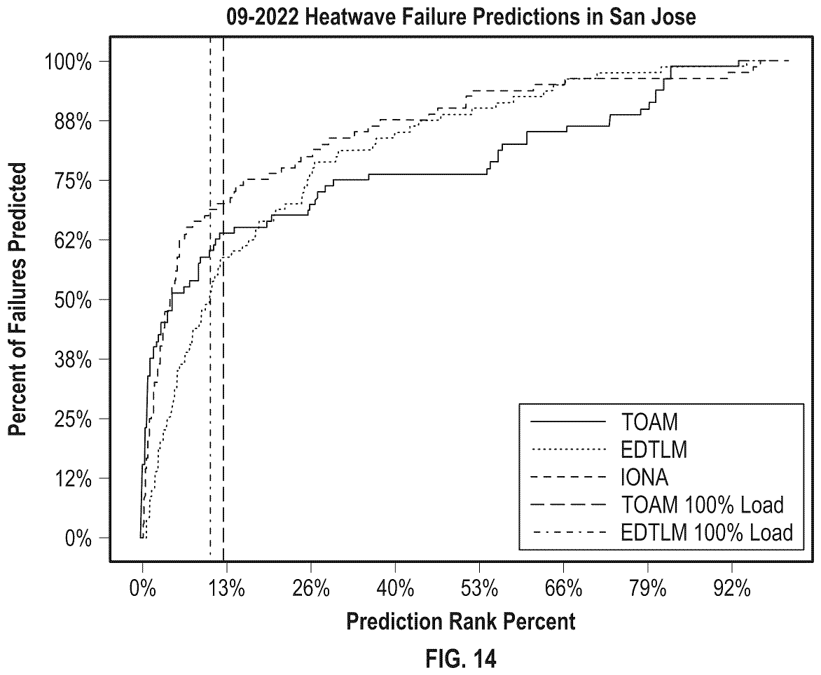

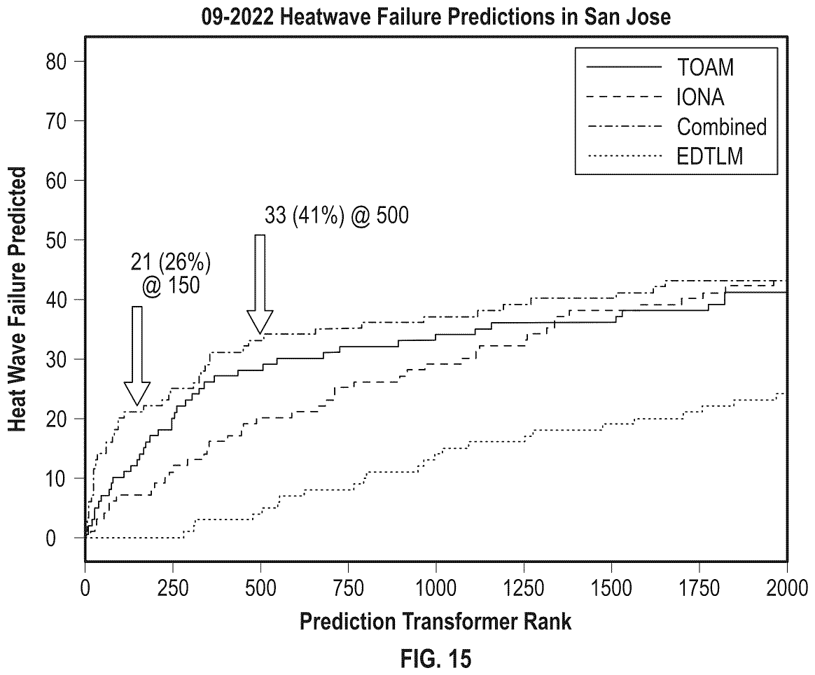

In some embodiments, the system is configured to execute a heat wave evaluation. In some embodiments, the model was run against a division for a heat wave. In some embodiments, to create a ranking of failure predictions, the model was used by the system to create a ranking of transformers by the adjusted overload rate. In some embodiments, this was compared to the EDTLM model by the system, using the max unit overloading rate. In some embodiments, other models which provided a probability of failure or magnitude of consequence were evaluated. FIGS. 13-15 show the results of the model according to some embodiments. In some embodiments, for developing high confidence predictions of transformer heat wave failures, TOAM dramatically outperforms other methods. An ensemble of TOAM and IONA is able to further improve results.

In some embodiments, the transformer overload accuracy model is configured to leverage physics, optimization, and unsupervised learning to enrich overload classification with new categories, which include confirmed overload, suspicious overload, suspicious normal confirmed normal, as non-limiting examples.

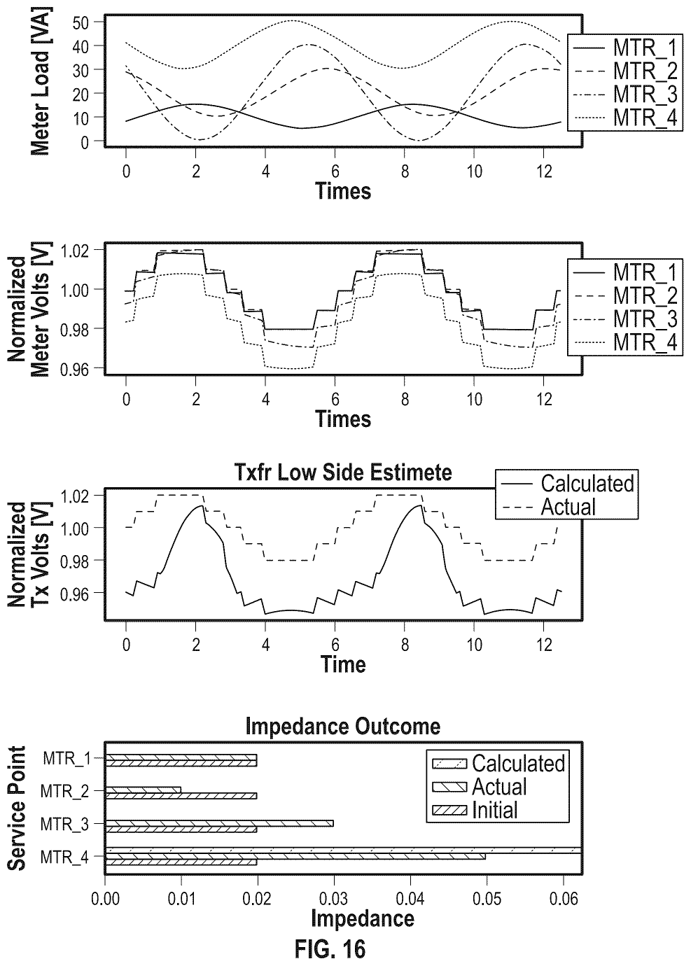

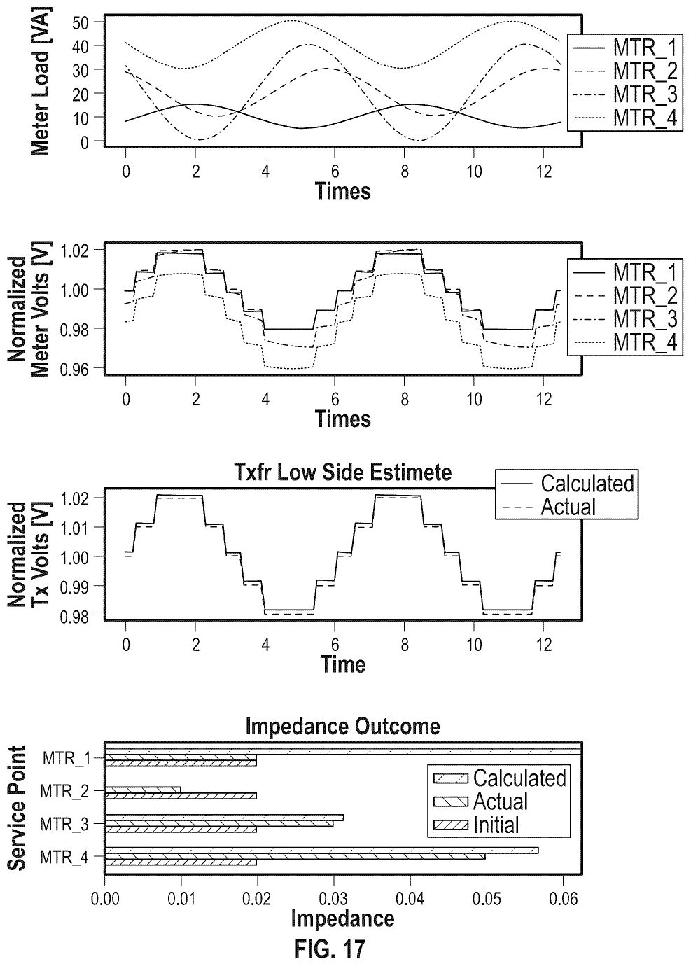

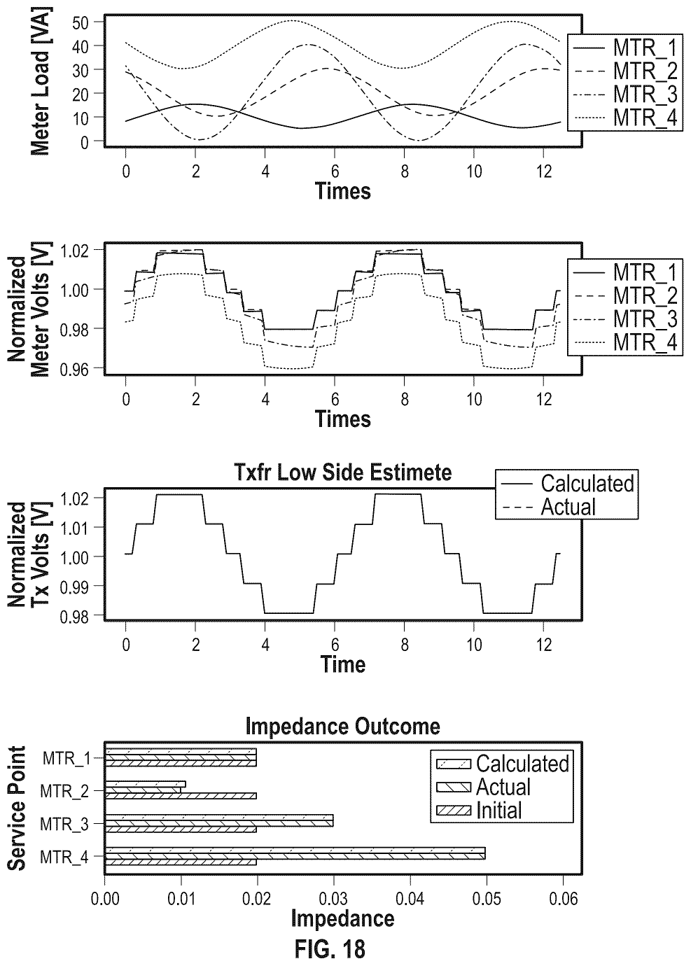

FIGS. 16-18 show the iterative process of convergence on the actual values according to some embodiments. In some embodiments, for given meter level voltages, the system uses estimates of the secondary impedance to calculate transformer side voltages. In some embodiments, the system uses the transformer voltage and impedances to estimate the meter voltage. In some embodiments, the system executes an SLQP bounded optimization (Z>0) to minimize the difference of the original meter voltages to the meter level estimates. In some embodiments, the estimated impedance values quickly converge to the actual values. In some embodiments, using low side voltages from neighboring transformers, a similar approach can be used by the system to estimate the voltage drop across the transformer and the voltage on the primary as described with regard to FIG. 7.

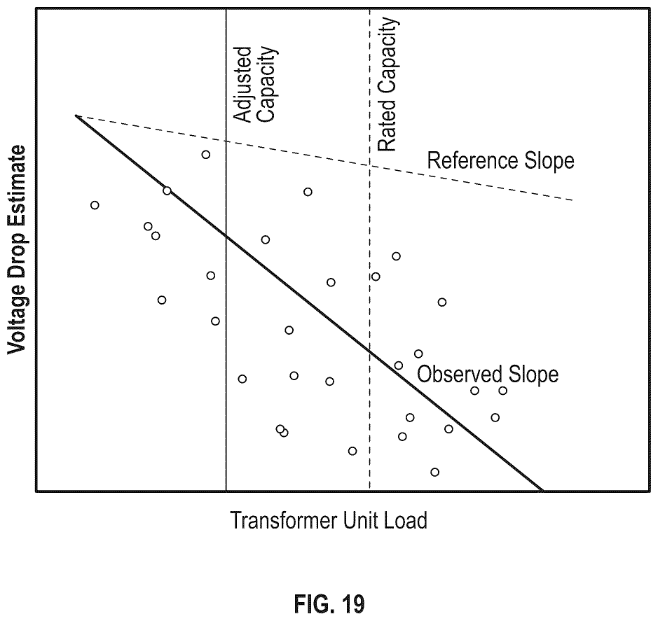

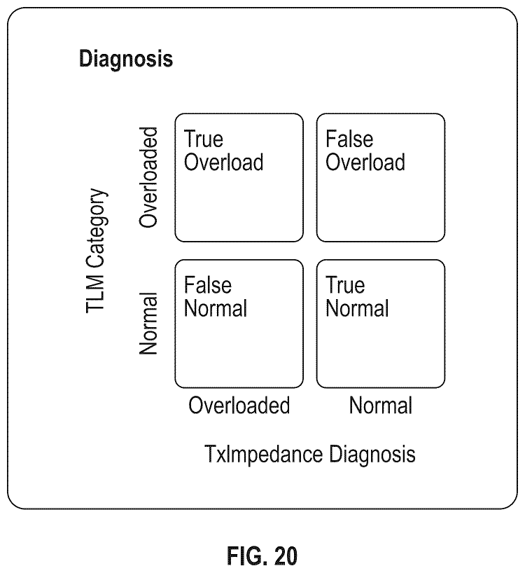

FIG. 19 illustrates a system generated alert where the reference slope deviates significantly from the observed slope according to some embodiments. In some embodiments, if we expect a slope of 2% on a 50 kVA transformer, but are observing a slope of 5%, we may actually have a 15 KVA transformer. FIG. 20 shows a diagnosis chart used by the system according to some embodiments.

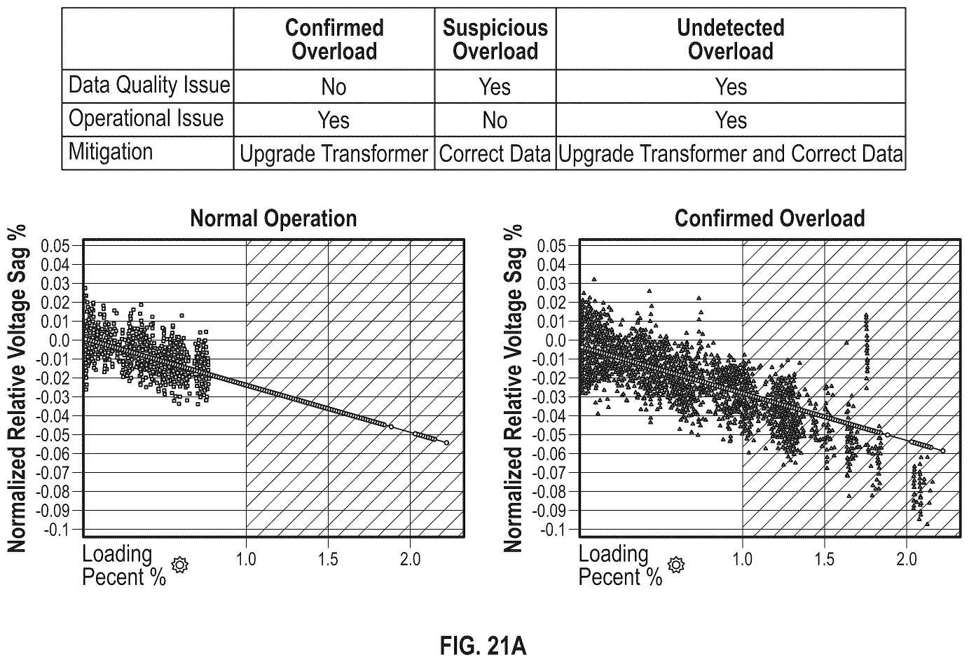

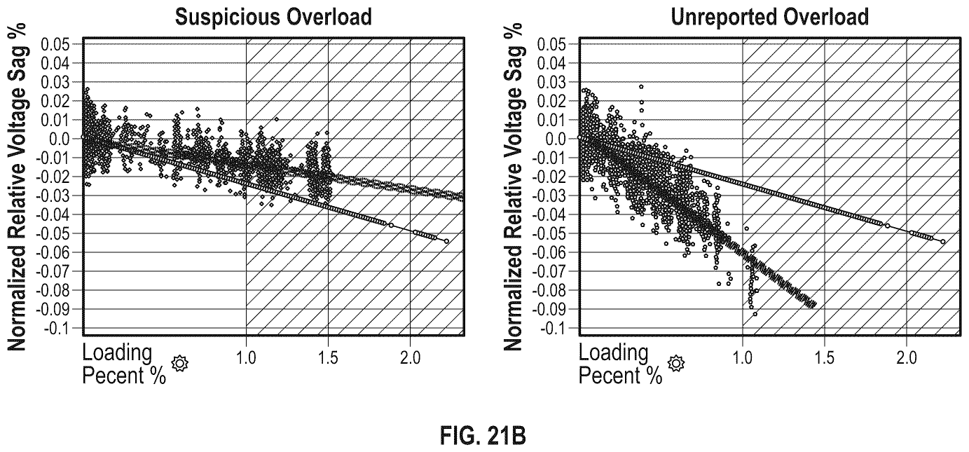

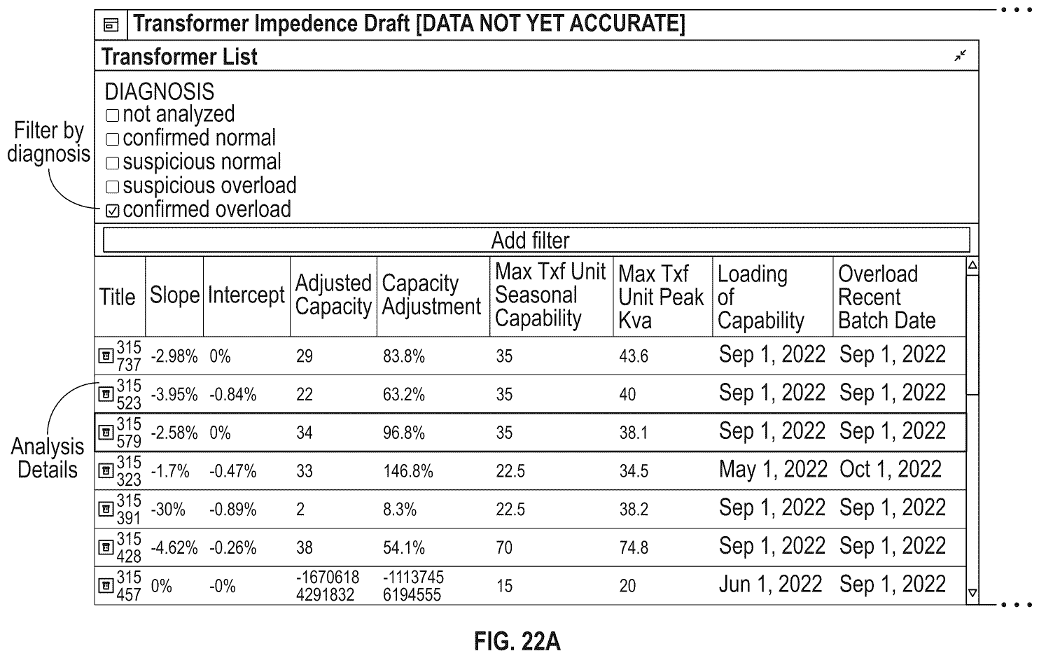

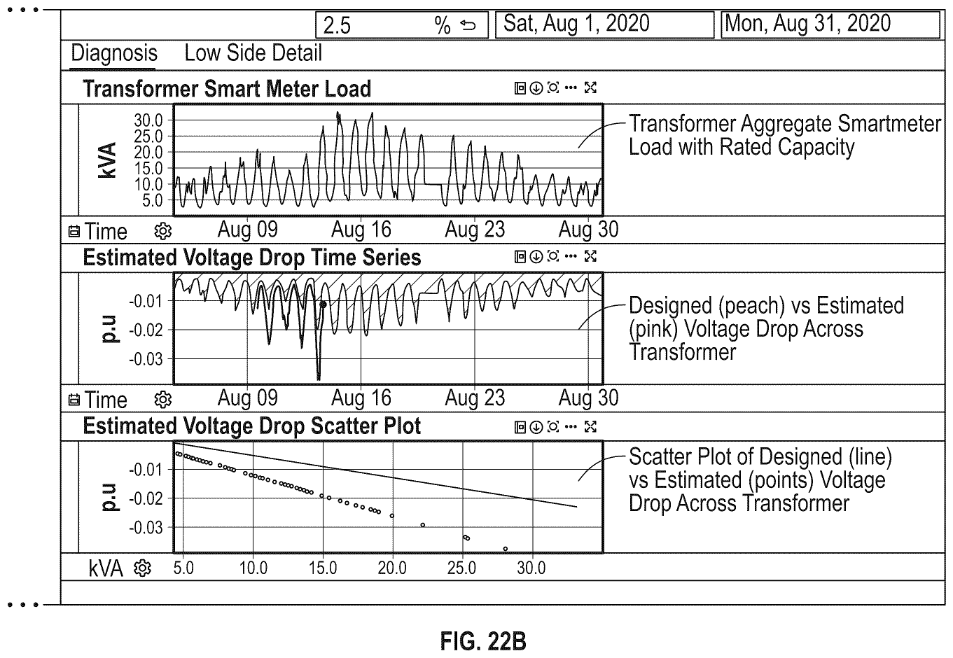

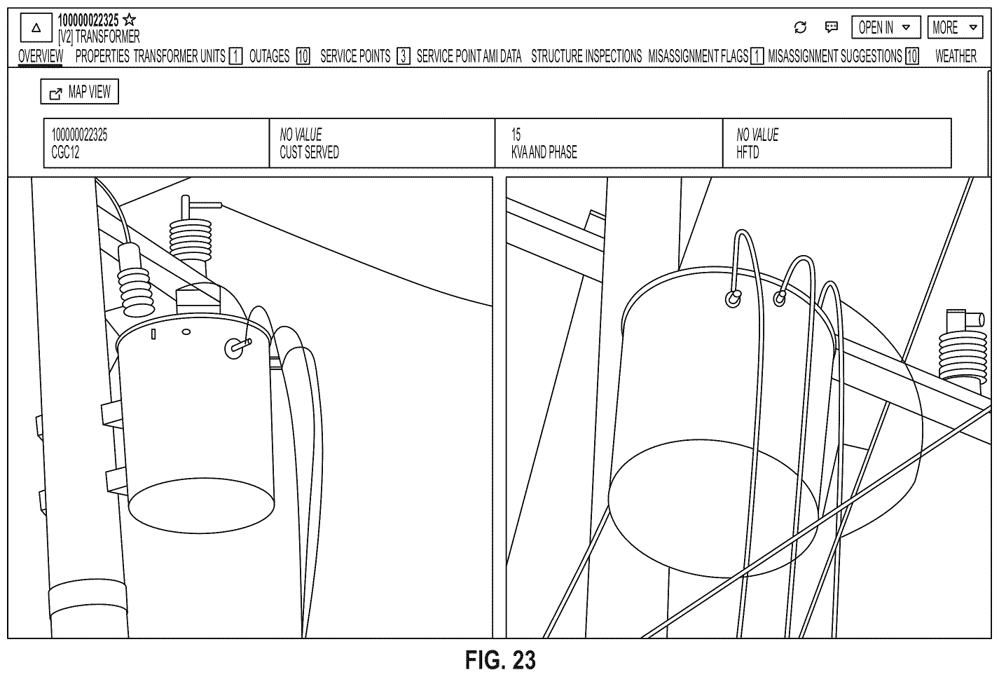

FIGS. 21A and 21B illustrate various system generated reports according to some embodiments. FIGS. 22A and 22B illustrate a first system generated GUI according to some embodiments. In some embodiments, GIS says it is 15 kVA, but desktop review shows a 50 kVA nameplate. FIG. 23 shows a desktop review according to some embodiments. In some embodiments, the system is configured to confirm that image capture date is relevant based on the transformer installation date. In some embodiments, this method is cost effective and quick compared to sending frontline teammates to go onsite or perform a 2nd level review before requesting more costly methods to confirm overloaded transformer.

In some embodiments, the system is configured to execute an identification of neighboring transformers. In some embodiments, neighboring transformers are converted using trace query to network graph analytics. In some embodiments, the system is configured to calculate distance between neighbors. In some embodiments, the system is configured to filter neighbors by distance. In some embodiments, the system is configured to filter neighbors by configuration. In some embodiments, the system is configured to execute an identification of previously missed neighbors.

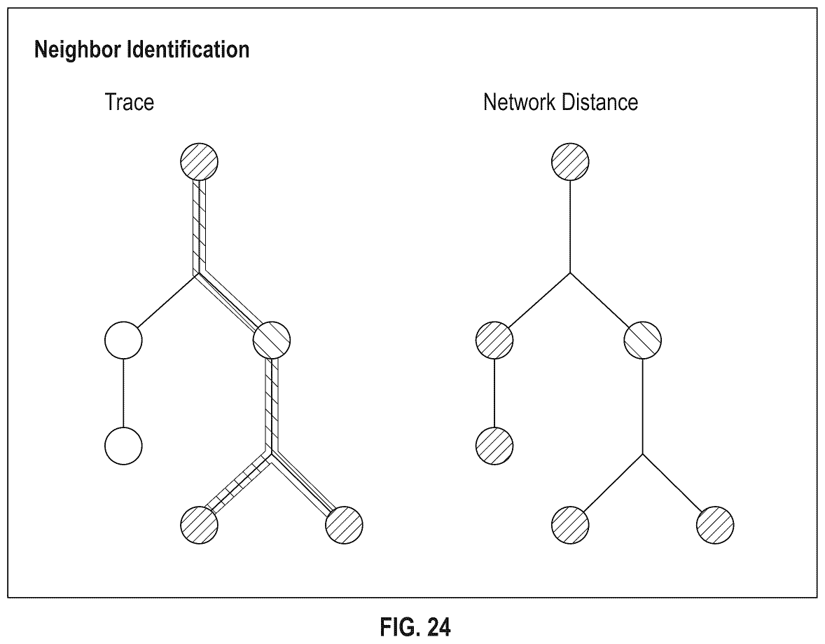

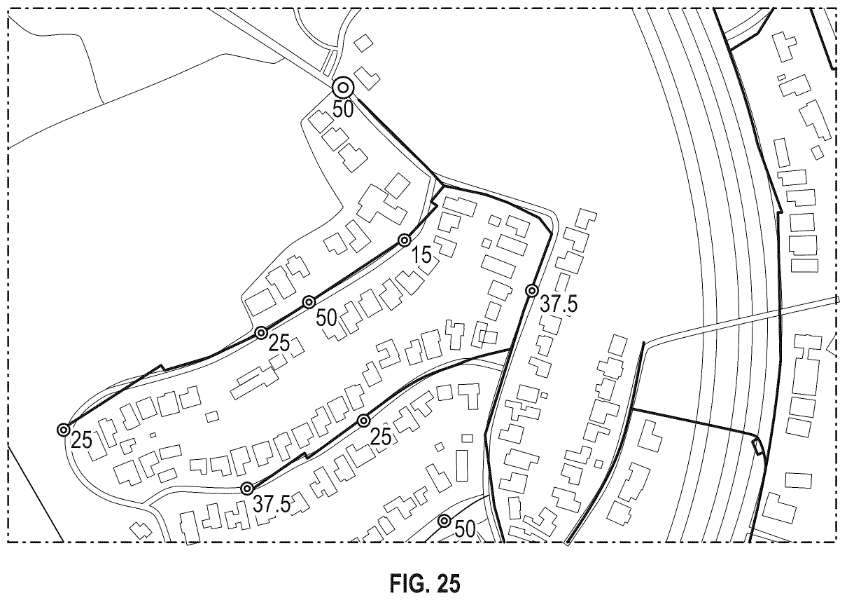

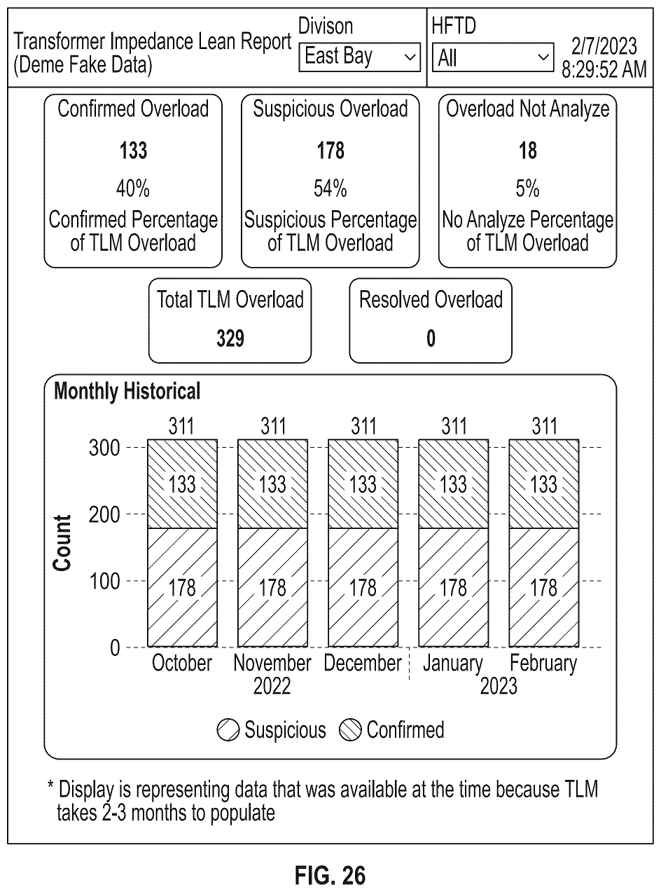

FIG. 24 illustrates neighbor identification according to some embodiments. In some embodiments, the system is configured to show selected and neighboring transformers in a map with transformer type label according to some embodiments. FIG. 25 shows a system generated map according to some embodiments. In some embodiments, the system is configured to generate a lean dashboard. In some embodiments, the dashboard includes a limited number of KPIs to monitor the health of program. In some embodiments, the dashboard is configured to display a status (e.g., a red, amber, green status) to make it obvious where attention is needed. FIG. 26 shows a lean dashboard according to some embodiments.

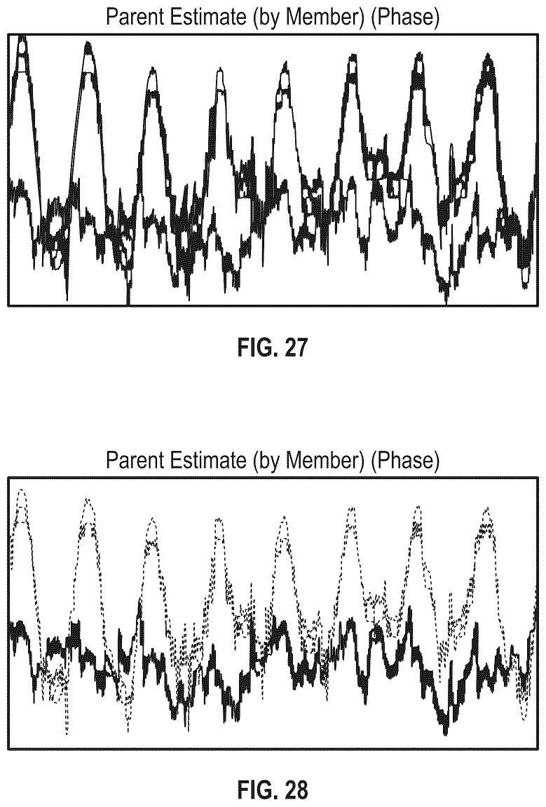

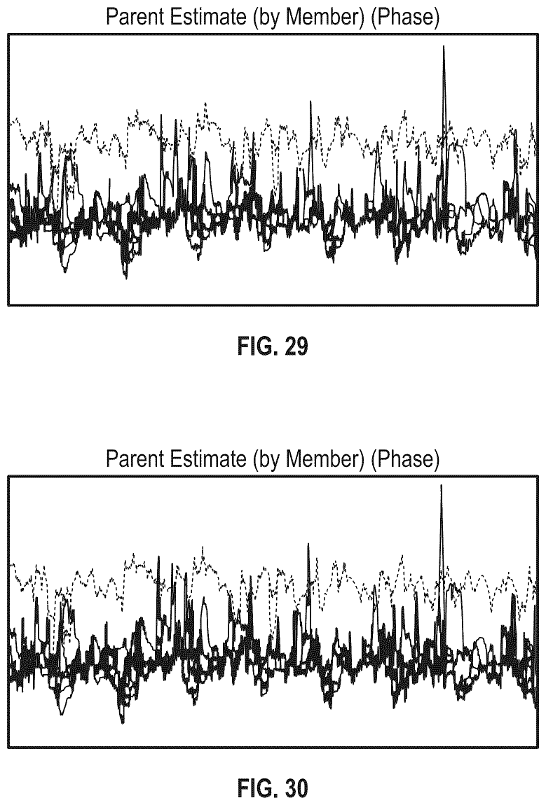

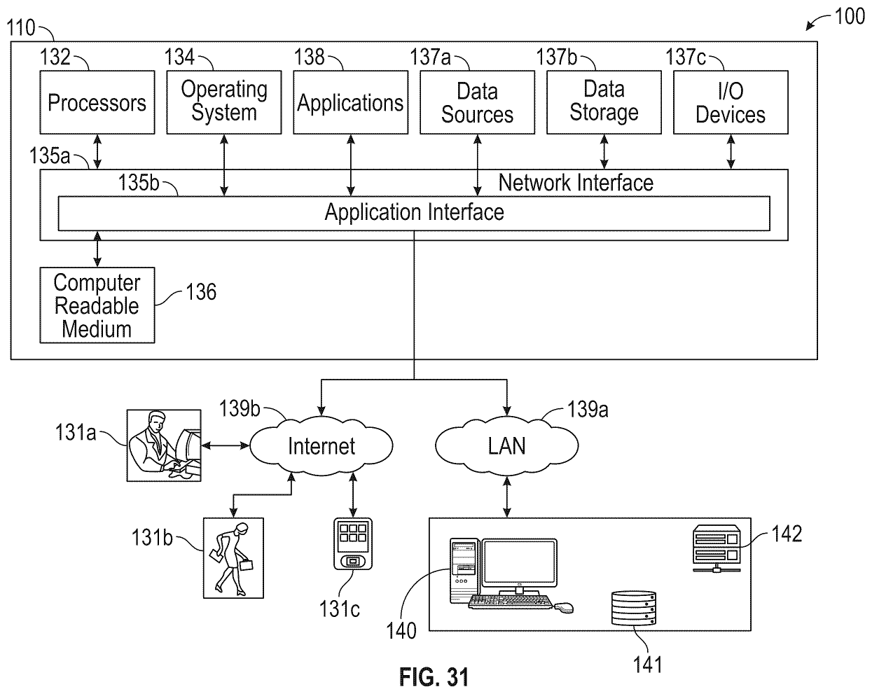

In some embodiments, the system is configured to implement noise and phase cluster handling. In some embodiments, the system implementation results in improved clustering to prevent disruption from noise measurements. FIG. 27 shows noise measurement according to some embodiments. In some embodiments, parameters optimized by the system to match target phase and reduce noise. In some embodiments, the system is configured to evenly distribute associated voltage to non-noise phases. FIG. 29 shows that sometimes the cluster that was categorized as noise will disrupt the impedance estimates of the other members. FIG. 30 illustrates that sometimes phases will be characterized as noise even though they are apparently in the same phase. In some embodiments, this is not a significant issue as the load would still be included but will impact the impedance estimates.

FIG. 31 illustrates a computer system 110 enabling or comprising the systems and methods in accordance with some embodiments. In some embodiments, the computer system 110 is configured to operate and/or process computer-executable code of one or more software modules of the aforementioned system and method. Further, in some embodiments, the computer system 110 is configured to operate and/or display information within one or more graphical user interfaces (e.g., HMIs) integrated with or coupled to the system.

In some embodiments, the computer system 110 comprises one or more processors 132. In some embodiments, at least one processor 132 resides in, or is coupled to, one or more servers. In some embodiments, the computer system 110 includes a network interface 135a and an application interface 135b coupled to the least one processor 132 capable of processing at least one operating system 134. Further, in some embodiments, the interfaces 135a, 135b coupled to at least one processor 132 are configured to process one or more of the software modules (e.g., such as enterprise applications 138). In some embodiments, the software application modules 138 includes server-based software. In some embodiments, the software application modules 138 are configured to host at least one user account and/or at least one client account, and/or are configured to operate to transfer data between one or more of these accounts using one or more processors 132.

With the above embodiments in mind, it is understood that the system is configured to execute various computer-implemented program steps involving data stored on one or more non-transitory computer media as recited above according to some embodiments. In some embodiments, the above-described databases and models described throughout this disclosure are configured to store analytical models and other data on non-transitory computer-readable storage media within the computer system 110 and on computer-readable storage media coupled to the computer system 110 according to some embodiments. In addition, in some embodiments, the above-described applications of the system are stored on computer-readable storage media within the computer system 110 and on computer-readable storage media coupled to the computer system 110. In some embodiments, these operations are those requiring physical manipulation of structures including electrons, electrical charges, transistors, amplifiers, receivers, transmitters, and/or any conventional computer hardware in order to transform an electrical input into a different output. In some embodiments, these structures include one or more of electrical, electromagnetic, magnetic, optical, and/or magneto-optical signals capable of being stored, transferred, combined, compared, and otherwise manipulated. In some embodiments, the computer system 110 comprises at least one computer readable medium 136 coupled to at least one of at least one data source 137a, at least one data storage 137b, and/or at least one input/output 137c. In some embodiments, the computer system 110 is embodied as computer readable code on a computer readable medium 136. In some embodiments, the computer readable medium 136 includes any data storage that stores data, which is configured to thereafter be read by a computer (such as computer 140). In some embodiments, the non-transitory computer readable medium 136 includes any physical or material medium that is used to tangibly store the desired information, steps, and/or instructions and which is configured to be accessed by a computer 140 or processor 132. In some embodiments, the non-transitory computer readable medium 136 includes hard drives, network attached storage (NAS), read-only memory, random-access memory, FLASH-based memory, CD-ROMs, CD-Rs, CD-RWs, DVDs, magnetic tapes, and/or other optical and non-optical data storage. In some embodiments, various other forms of computer-readable media 136 are configured to transmit or carry instructions to one or more remote computers 140 and/or at least one user 131, including a router, private or public network, or other transmission or channel, both wired and wireless. In some embodiments, the software application modules 138 are configured to send and receive data from a database (e.g., from a computer readable medium 136 including data sources 137a and data storage 137b that comprises a database), and data is configured to be received by the software application modules 138 from at least one other source. In some embodiments, at least one of the software application modules 138 are configured to be implemented by the computer system 110 to output data to at least one user 131 via at least one graphical user interface rendered on at least once digital display.

In some embodiments, the one or more non-transitory computer readable 136 media are distributed over a conventional computer network via the network interface 135a where some embodiments stored the non-transitory computer readable media are stored and executed in a distributed fashion. For example, in some embodiments, one or more components of the computer system 110 are configured to send and/or receive data through a local area network (“LAN”) 139a and/or an internet coupled network 139b (e.g., such as a wireless internet). In some embodiments, the networks 139a, 139b include one or more wide area networks (“WAN”), direct connections (e.g., through a universal serial bus port), or other forms of computer-readable media 136, and/or any combination thereof.

In some embodiments, components of the networks 139a, 139b include any number of personal computers 140 which include for example desktop computers, laptop computers, and/or any fixed, generally non-mobile internet appliances coupled through the LAN 139a. For example, some embodiments include one or more personal computers 140, databases 141, and/or servers 142 coupled through the LAN 139a that are configured for use by any type of user including an administrator. Some embodiments include one or more personal computers 140 coupled through network 139b. In some embodiments, one or more components of the computer system 110 are configured to send or receive data through an internet network (e.g., such as network 139b). For example, some embodiments include at least one user 131a, 131b, coupled wirelessly and accessing one or more software modules of the system including at least one enterprise application 138 via an input and output (“I/O”) 137c. In some embodiments, the computer system 110 is configured to enable at least one user 131a, 131b, to be coupled to access enterprise applications 138 via an I/O 137c through LAN 139a. In some embodiments, the user 131 includes a user 131a coupled to the computer system 110 using a desktop computer, and/or laptop computers, or any fixed, generally non-mobile internet appliances coupled through the internet 139b. In some embodiments, the user includes a mobile user 131b coupled to the computer system 110. In some embodiments, the user 131b connects using any mobile computing 131c to wireless coupled to the computer system 110, including, but not limited to, one or more personal digital assistants, at least one cellular phone, at least one mobile phone, at least one smart phone, at least one pager, at least one digital tablet, and/or at least one fixed or mobile internet appliances.

The disclosure describes the specifics of how a machine including one or more computers comprising one or more processors and one or more non-transitory computer readable media implement the system and its improvements over the prior art. The instructions executed by the machine cannot be performed in the human mind or derived by a human using a pen and paper but require the machine to convert process input data to useful output data. Moreover, the claims presented herein do not attempt to tic-up a judicial exception with known conventional steps implemented by a general-purpose computer; nor do they attempt to tic-up a judicial exception by simply linking it to a technological field. Indeed, the systems and methods described herein were unknown and/or not present in the public domain at the time of filing, and they provide technologic improvements and advantages not known in the prior art. Furthermore, the system includes unconventional steps that confine the claim to a useful application.

It is understood that the system is not limited in its application to the details of construction and the arrangement of components set forth in the previous description or illustrated in the drawings. The system and methods disclosed herein fall within the scope of numerous embodiments. The previous discussion is presented to enable a person skilled in the art to make and use embodiments of the system. Any portion of the structures and/or principles included in some embodiments can be applied to any and/or all embodiments: it is understood that features from some embodiments presented herein are combinable with other features according to some other embodiments. Thus, some embodiments of the system are not intended to be limited to what is illustrated but are to be accorded the widest scope consistent with all principles and features disclosed herein.

Some embodiments of the system are presented with specific values and/or setpoints. These values and setpoints are not intended to be limiting and are merely examples of a higher configuration versus a lower configuration and are intended as an aid for those of ordinary skill to make and use the system.

Any text in the drawings are part of the system's disclosure and is understood to be readily incorporable into any description of the metes and bounds of the system. Any functional language in the drawings is a reference to the system being configured to perform the recited function, and structures shown or described in the drawings are to be considered as the system comprising the structures recited therein. Any figure depicting a content for display on a graphical user interface is a disclosure of the system configured to generate the graphical user interface and configured to display the contents of the graphical user interface. It is understood that defining the metes and bounds of the system using a description of images in the drawing does not need a corresponding text description in the written specification to fall with the scope of the disclosure.

Furthermore, acting as Applicant's own lexicographer, Applicant imparts the explicit meaning and/or disavow of claim scope to the following terms:

Applicant defines any use of “and/or” such as, for example, “A and/or B,” or “at least one of A and/or B” to mean element A alone, element B alone, or elements A and B together. In addition, a recitation of “at least one of A, B, and C,” a recitation of “at least one of A, B, or C,” or a recitation of “at least one of A, B, or C or any combination thereof” are each defined to mean element A alone, element B alone, element C alone, or any combination of elements A, B and C, such as AB, AC, BC, or ABC, for example.

“Substantially” and “approximately” when used in conjunction with a value encompass a difference of 5% or less of the same unit and/or scale of that being measured.

“Simultaneously” as used herein includes lag and/or latency times associated with a conventional and/or proprietary computer, such as processors and/or networks described herein attempting to process multiple types of data at the same time. “Simultaneously” also includes the time it takes for digital signals to transfer from one physical location to another, be it over a wireless and/or wired network, and/or within processor circuitry.

As used herein, “can” or “may” or derivations there of (e.g., the system display can show X) are used for descriptive purposes only and is understood to be synonymous and/or interchangeable with “configured to” (e.g., the computer is configured to execute instructions X) when defining the metes and bounds of the system. The phrase “configured to” also denotes the step of configuring a structure or computer to execute a function according to some embodiments.

In addition, the term “configured to” means that the limitations recited in the specification and/or the claims must be arranged in such a way to perform the recited function: “configured to” excludes structures in the art that are “capable of” being modified to perform the recited function but the disclosures associated with the art have no explicit teachings to do so. For example, a recitation of a “container configured to receive a fluid from structure X at an upper portion and deliver fluid from a lower portion to structure Y” is limited to systems where structure X, structure Y, and the container are all disclosed as arranged to perform the recited function. The recitation “configured to” excludes elements that may be “capable of” performing the recited function simply by virtue of their construction but associated disclosures (or lack thereof) provide no teachings to make such a modification to meet the functional limitations between all structures recited. Another example is “a computer system configured to or programmed to execute a series of instructions X, Y, and Z.” In this example, the instructions must be present on a non-transitory computer readable medium such that the computer system is “configured to” and/or “programmed to” execute the recited instructions: “configure to” and/or “programmed to” excludes art teaching computer systems with non-transitory computer readable media merely “capable of” having the recited instructions stored thereon but have no teachings of the instructions X, Y, and Z programmed and stored thereon. The recitation “configured to” can also be interpreted as synonymous with operatively connected when used in conjunction with physical structures.

It is understood that the phraseology and terminology used herein is for description and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

The previous detailed description is to be read with reference to the figures, in which like elements in different figures have like reference numerals. The figures, which are not necessarily to scale, depict some embodiments and are not intended to limit the scope of embodiments of the system.

Any of the operations described herein that form part of the system are useful machine operations. The system also relates to a device or an apparatus for performing these operations. All flowcharts presented herein represent computer implemented steps and/or are visual representations of algorithms implemented by the system. The apparatus can be specially constructed for the required purpose, such as a special purpose computer. When defined as a special purpose computer, the computer can also perform other processing, program execution or routines that are not part of the special purpose, while still being capable of operating for the special purpose. Alternatively, the operations can be processed by a general-purpose computer selectively activated or configured by one or more computer programs stored in the computer memory, cache, or obtained over a network. When data is obtained over a network the data can be processed by other computers on the network, e.g., a cloud of computing resources.

The embodiments of the system can also be defined as a machine that transforms data from one state to another state. The data can represent an article, which can be represented as an electronic signal and electronically manipulate data. The transformed data can, in some cases, be visually depicted on a display, representing the physical object that results from the transformation of data. The transformed data can be saved to storage, or in particular formats that enable the construction or depiction of a physical and tangible object. In some embodiments, the manipulation can be performed by a processor. In such an example, the processor thus transforms the data from one thing to another. Still further, some embodiments include methods can be processed by one or more machines or processors that can be connected over a network. Each machine can transform data from one state or thing to another, and can also process data, save data to storage, transmit data over a network, display the result, or communicate the result to another machine. Computer-readable storage media, as used herein, refers to physical or tangible storage (as opposed to signals) and includes without limitation volatile and non-volatile, removable, and non-removable storage media implemented in any method or technology for the tangible storage of information such as computer-readable instructions, data structures, program modules or other data.

Although method operations are presented in a specific order according to some embodiments, the execution of those steps do not necessarily occur in the order listed unless explicitly specified. Also, other housekeeping operations can be performed in between operations, operations can be adjusted so that they occur at slightly different times, and/or operations can be distributed in a system which allows the occurrence of the processing operations at various intervals associated with the processing, as long as the processing of the overlay operations are performed in the desired way and result in the desired system output.

It will be appreciated by those skilled in the art that while the system has been described above in connection with particular embodiments and examples, the system is not necessarily so limited, and that numerous other embodiments, examples, uses, modifications and departures from the embodiments, examples and uses are intended to be encompassed by the claims attached hereto. The entire disclosure of each patent and publication cited herein is incorporated by reference, as if each such patent or publication were individually incorporated by reference herein. Various features and advantages of the system are set forth in the following claims.

We claim:

1. A system for estimating high-side voltage of transformers in an electrical distribution network, comprising:
one or more computers comprising one or more processors and one or more non-transitory computer readable media, the one or more non-transitory computer readable media comprising program instructions stored thereon that when executed cause the one or more computers to:
receive, by the one or more processors, meter load and voltage data from one or more smart meters coupled to one or more transformers;
execute, by the one or more processors, an assumption for an impedance value for each of the one or more transformers;
determine, by the one or more processors, a low-side voltage of a transformer using the assumption; and
execute, by the one or more processors, an estimation of a high-side voltage of the transformer using the determined transformer low-side voltage;
wherein the system is configured to compare the estimation against known high-side voltage estimates to identify one or more discrepancies; and
wherein the system is configured to output a graphical user interface with the one or more discrepancies.

2. The system of claim 1,
wherein the one or more non-transitory computer readable media include further program instructions stored thereon configured to cause the one or more computers to:
optimize, by the one or more processors, impedance selection to minimize error between estimated and measured voltages.

3. The system of claim 2,
wherein the system is configured to execute clustering of voltage estimates to identify similar phases among neighboring transformers.

4. The system of claim 3,
wherein the system is configured to alert users through the graphical user interface when the estimated high-side voltage deviates beyond a predefined threshold from the known high-side voltage estimates.

5. The system of claim 1,
wherein the one or more non-transitory computer readable media comprise further program instructions stored thereon that cause the one or more computers to:
determine, by the one or more processors, an expected percent impedance for the one or more transformers from historical and specification data.

6. The system of claim 5,
wherein the system is configured to estimate impedance characteristics based on smart meter voltage and/or load readings on a low-side of the one or more transformers.

7. The system of claim 6,
wherein the system is configured to generate reports of voltage estimations and/or detected transformer variances.

8. The system of claim 1,
wherein the one non-transitory computer readable media comprise further program instructions stored thereon that cause the one or more computers to:
determine, by the one or more processors, a relationship between calculated voltage drop and expected impedance values for anomaly detection.

9. The system of claim 8,
wherein the system is configured to correct for discrepancies in transformer records by using neighbor transformer comparisons.

10. The system of claim 9,
wherein the system is configured to output corrected transformer parameters as an input into voltage drop calculations.

11. The system of claim 1,
wherein the system is configured to refine the estimation of the high-side voltage using collected data.

12. The system of claim 1,
wherein the system is configured to adjust calculations based on clustering analysis of other transformers in similar network conditions.

13. The system of claim 1,
wherein the system is configured to leverage historical voltage drop data to optimize transformer voltage estimation models.

14. The system of claim 1,
wherein the system is configured to enable users to manually input one or more values for calculated impedances and voltage estimations.

15. The system of claim 1,
wherein the non-transitory computer readable media comprise further program instructions stored thereon that cause the one or more computers to:
execute, by the one or more processors, near real-time voltage estimation updates during identified network loading changes.

16. The system of claim 15,
wherein the system is configured to employ a comparative analysis of neighboring transformer high-side estimates.

17. The system of claim 16,
wherein the system is configured to send a notification upon detecting repeated discrepancies.

18. The system of claim 17,
wherein the system is configured to enable a user to define a preconfigured risk level for the one or more transformers; and
wherein the system is configured to execute a threshold notification at the preconfigured risk level.
